(19) United States
(12) Patent Application Publication
(10) Pub. No.: US 2025/0169172 A1
(43) Pub. Date: May 22, 2025

(54) MERGED BACKSIDE CONTACT ISOLATION

(71) Applicant: International Business Machines Corporation, Armonk, NY (US)

(72) Inventors: Lijuan Zou, Slingerlands, NY (US); Tao Li, Slingerlands, NY (US); Ruilong Xie, Niskayuna, NY (US); Chih-Chao Yang, Glenmont, NY (US)

(21) Appl. No.: 18/511,265

(22) Filed: Nov. 16, 2023

(51) Int. Cl. H01L 27/092; H01L 21/762; H01L 23/528; H01L 29/417

(52) U.S. Cl. CPC H10D 84/85; H01L 21/76224; H01L 23/5286; H10D 64/254

(57) ABSTRACT

A semiconductor device includes a dielectric isolation bar disposed in a region between an n-type active region and a p-type active region. The dielectric isolation bar has a first tapered portion disposed within a contact where the contact connects to the n-type active region or the p-type active region and a second tapered portion that cuts through portions of a buried power rail layer, wherein the dielectric isolation bar electrically isolates a lateral portion of the contact from surrounding structures and separates portions of the buried power rail layer.

### BACKGROUND

The present invention generally relates to semiconductor devices and processing methods, and more particularly to stacked field effect transistors (FETs) with backside contacts which are isolated from each other using dielectric isolation bars.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors near one another places spatial and electrical constraints that can make it challenging to provide required performance.

Active regions formed by epitaxial growth processes have become increasingly smaller in size. As a result, contacts to the epitaxial regions shrink as well. When the contacts become too small, they can no longer be printed using lithographic processes. The reduction in device pitch makes providing isolation between active regions and the contacts that connect to these active regions more difficult.

Therefore, a need exists to form contacts that are properly isolated from each other and from surrounding conductive structures in high density devices.

### SUMMARY

In accordance with an embodiment of the present invention, a semiconductor device includes a contact connecting a buried power rail to an active region. A dielectric isolation bar is disposed in a location between an n-type active region and a p-type active region having a first tapered portion disposed within the contact and a second tapered portion disposed within a buried power rail layer to electrically isolate the contact and portions of the buried power rail layer.

In accordance with another embodiment of the present invention, a semiconductor device includes an n-type active region disposed adjacent to a p-type active region. A merged contact has a first portion connecting the n-type active region to a first buried power rail and a second portion connecting the p-type active region to second buried power rail. A dielectric isolation bar is disposed between the first portion and the second portion of the merged contact and between the first buried power rail and the second buried power rail to electrically isolate the first portion of the merged contact from the second portion of the merged contact and the first buried power rail from the second buried power rail.

In accordance with another embodiment of the present invention, a method for fabrication of a semiconductor device includes removing a substrate to expose a dielectric liner covering shallow trench isolation (STI) regions and to expose sacrificial placeholders associated with active regions; forming an interlevel dielectric layer over the dielectric liner and the sacrificial placeholders; patterning contact openings in the interlevel dielectric layer, the contact openings including single contact openings and merged contact openings and removing the sacrificial placeholders from the contact openings. Contacts are formed in the single contact openings and the merged contact openings at locations between active regions with opposite conductivity. A buried rail layer is deposited in contact with the contacts and trenches are formed through the buried rail layer and into the contacts. A dielectric fill is deposited in the trenches to form dielectric isolation regions that isolate portions of the buried rail layer to form buried power rails and isolate portions of the contacts at the locations between active regions with opposite conductivity.

In one embodiment, a semiconductor device includes a dielectric isolation bar disposed in a region between an n-type active region and a p-type active region. The dielectric isolation bar has a first tapered portion disposed within a contact where the contact connects to one of the n-type active region and the p-type active region and a second tapered portion that cuts through portions of a buried power rail layer, wherein the dielectric isolation bar electrically isolates a lateral portion of the contact from surrounding structures and separates portions of the buried power rail layer.

In some embodiments, the first tapered portion and the second tapered portion have discontinuous sidewalls through the contact and the buried power rail layer. The first tapered portion can include a sub-lithographic size. The contact can include a top portion that is narrower that its lower portion. The top portion can be disposed within portions of a dielectric liner. The dielectric isolation bar can overlap the portions of the dielectric liner to provide a continuous dielectric barrier. The contact can extend into a gouged portion of an active region.

In other embodiments, a semiconductor device includes an n-type active region disposed adjacent to a p-type active region and a merged contact having a first portion connecting the n-type active region to a first buried power rail and a second portion connecting the p-type active region to second buried power rail. A dielectric isolation bar is disposed through the merged contact to cut the merged contact into the first portion and the second portion. The dielectric isolation bar is disposed between the first buried power rail and the second buried power rail to electrically isolate the first portion of the merged contact from the second portion of the merged contact and the first buried power rail from the second buried power rail.

In some embodiments, the dielectric isolation bar includes a tapered shape having continuous sidewalls through the merged contact and a buried power rail layer which includes the first buried power rail and the second buried power rail. The tapered shape can taper from a critical dimension to a sub-lithographic size. The first portion of the merged contact and the second portion of the merged contact can each include a top portion that is narrower that its lower portion. The top portion can be disposed within portions of a dielectric liner. The dielectric isolation bar can overlap the portions of the dielectric liner to provide a continuous dielectric barrier. The first portion of the merged contact and the second portion of the merged contact can extend into gouges in the n-type active region and the p-type active region, respectively.

In other embodiments, a semiconductor device includes a first dielectric isolation bar disposed within a single contact between an n-type active region and an adjacent a p-type active region and a second dielectric isolation bar disposed through a merged contact between an n-type active region and an adjacent a p-type active region. The second dielectric isolation bar separates the merged contact to connect one portion of the merged contact to the n-type active region and another portion of the merged contact to the p-type active region. The first dielectric isolation bar and the second dielectric isolation bar pass through a power rail layer to define buried power rails.

In some embodiments, the second dielectric isolation bar includes a tapered shape having continuous sidewalls through the merged contact and the power rail layer. The tapered shape can taper from a critical dimension to a sub-lithographic size. The first dielectric isolation bar can include discontinuous sidewalls through the single contact and the power rail layer. The first and second dielectric isolation bars can overlap portions of a dielectric liner to provide a continuous dielectric barrier. At least one contact can include a portion that extends into a gouged portion of an active region.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view, taken at section line Y1 as shown in an inset (and referred to as section Y1), of a semiconductor substrate having active regions with different conductivities, in accordance with an embodiment of the present invention;

FIG. 2 shows a cross-sectional view, taken at section line Y1, with a portion of the substrate removed to an etch stop layer, in accordance with an embodiment of the present invention;

FIG. 3 shows a cross-sectional view, taken at section line Y1, with the etch stop layer removed, in accordance with an embodiment of the present invention;

FIG. 4 shows a cross-sectional view, taken at section line Y1, with a remaining portion of the substrate removed, in accordance with an embodiment of the present invention;

FIG. 5 shows a cross-sectional view, taken at section line Y1, with an interlevel dielectric layer formed, in accordance with an embodiment of the present invention;

FIG. 6 shows a cross-sectional view, taken at section line Y1, with contact openings opened up to expose active regions, gouges in the active regions are also shown, in accordance with an embodiment of the present invention;

FIG. 7 shows a cross-sectional view, taken at section line Y1, with contact openings filled and including gouge portions of the contacts, in accordance with an embodiment of the present invention;

FIG. 8 shows a cross-sectional view, taken at section line Y1, with a buried rail layer formed, in accordance with an embodiment of the present invention;

FIG. 9 shows a cross-sectional view, taken at section line Y1, with trenches formed through the buried rail layer and into the contacts, in accordance with an embodiment of the present invention;

FIG. 10 shows a cross-sectional view, taken at section line Y1, with the trenches filled to form dielectric isolation bars through the buried rail layer and into the contacts, in accordance with an embodiment of the present invention;

FIG. 11 shows a cross-sectional view, taken at section line Y1, a backside power distribution network formed, in accordance with an embodiment of the present invention; and

FIG. 12 shows a flow chart for methods for fabricating a semiconductor, in accordance with an embodiment of the present invention.

### DETAILED DESCRIPTION

In accordance with embodiments of the present invention, devices and methods are described which employ dielectric isolation bars adjacent to or between contacts to enable spacings below lithographic process sizes in a stacked field effect transistor (FET) device. The dielectric isolation bars can provide needed isolation by subtractive metal patterning between power rails and contacts followed by dielectric isolation deposition. In one particularly useful embodiment, a combination of subtractive metal patterning at a backside power rail (BSPR) and backside source/drain (S/D) contact is employed. This approach patterns supply voltage (Vdd) and ground (Vss) backside power rails and isolates merged n-type field effect transistor (NFET) to p-type field effect transistor (PFET) transistor (N2P) contacts in a single step.

In embodiments of the present invention, a semiconductor device includes a dielectric isolation bar that isolates a backside power rail and merged backside S/D contacts between an NFET and a PFET, where the dielectric isolation bar has a lower portion that isolates the backside power rails and an upper portion that cuts through the backside S/D contact.

In one embodiment, the dielectric isolation bar can cut through a merged backside S/D contact in a region between an NFET and a PFET and have continuous sidewalls throughout a lower portion and an upper portion. In another embodiment, the dielectric isolation bar cuts through a single backside S/D contact under either the NFET or the PFET and has a discontinuous dimension, where a lower portion dimensions is larger than an upper portion dimension. For example, one dielectric isolation bar includes an upper portion and a lower portion that have sidewalls that are continuous. Another dielectric isolation bar includes sidewalls that are discontinuous from an upper portion to a lower portion and the lower portion follows the sidewall angle of a backside S/D contact.

In useful embodiments, a semiconductor wafer includes a semiconductor substrate. A semiconductor device is provided by growing an active region, e.g., a source/drain (S/D) epitaxial grown (epi) region. These active regions can include transistors of different conductivity types adjacent to one another. Due to node sizes that are below critical dimensions (CD) that can be provided by current lithographic techniques, merged contacts can be employed. However, these merged contacts cannot be employed to access both transistors of opposite conductivity types (NFET versus PFET). In accordance with the present embodiments, dielectric isolation bars are employed which can begin with lithographic critical dimensions but are reduced by employing etch chemistries that provide a tapered sidewall for an etched hole or trench for the dielectric isolation bars. This enables the use of smaller epi regions, merged contacts between transistors that need to be electrically isolated, and a scaling up level for connections to power distribution wiring. In other embodiments, where single contacts are employed, a dielectric isolation bar can be formed on a side of a contact to ensure sufficient dielectric isolation is provided to isolate the contact from surrounding structures.

In embodiments of the present invention, a semiconductor device includes a contact connecting a buried power rail to an active region and a dielectric isolation bar disposed in a location between an n-type active region and a p-type active region having a first tapered portion disposed within the contact and a second tapered portion disposed within a buried power rail layer to electrically isolate the contact and portions of the buried power rail layer. In this way, contacts and power rails have sufficient dielectric material for electrical isolations. This is particularly useful where NFETs and PFETs are adjacent to one another in a row of devices. The location between an n-type active region and a p-type active region is the contact level where the contact has an n-type active region on one side and a p-type active region on the other side of the contact.

In some embodiments, the first tapered portion and the second tapered portion have discontinuous sidewalls through the contact and the buried power rail layer. The first tapered portion can include a sub-lithographic size. The contact can include a top portion that is narrower that its lower portion. The top portion can be formed within portions of a dielectric liner. The dielectric isolation bar can overlap the portions of a dielectric liner to provide a continuous dielectric barrier. The contact can include a portion that extends into a gouge in the active region.

Another semiconductor device, in accordance with embodiments of the present invention includes an n-type active region disposed adjacent to a p-type active region and a merged contact having a first portion connecting the n-type active region to a first buried power rail and a second portion connecting the p-type active region to second buried power rail. A dielectric isolation bar is disposed between the first portion and the second portion of the merged contact and between the first buried power rail and the second buried power rail to electrically isolate the first portion of the merged contact from the second portion of the merged contact and the first buried power rail from the second buried power rail. Contacts and power rails have sufficient dielectric material for electrical isolation from merged contacts and/or single contacts. This is particularly useful where NFETs and PFETs are adjacent to one another in a row of devices.

In some embodiments, the dielectric isolation bar can include a tapered shape having continuous sidewalls through the merged contact and a buried power rail layer which includes the first buried power rail and the second buried power rail. The tapered shape can taper from a critical dimension to a sub-lithographic size. The first portion of the merged contact and the second portion of the merged contact can each include a top portion that is narrower that its lower portion. The top portion can be formed within portions of a dielectric liner. The dielectric isolation bar can overlap the portions of a dielectric liner to provide a continuous dielectric barrier. The first portion of the merged contact and the second portion of the merged contact can each extend into the n-type active region and the p-type active region, respectively.

In another embodiment, a method for fabrication of a semiconductor device includes removing a substrate to expose a dielectric liner covering shallow trench isolation (STI) regions and to expose sacrificial placeholders associated with active regions. An interlevel dielectric layer is formed over the dielectric liner and the sacrificial placeholders and contact openings are patterned in the interlevel dielectric layer, the contact openings include single contact openings and merged contact openings. The sacrificial placeholders are removed from the contact openings and contacts are formed in the single contact openings and the merged contact openings, at locations between active regions with opposite conductivity. A buried power rail layer is deposited in contact with the contacts and trenches are formed through the buried power rail layer and into the contacts. A dielectric fill is deposited in the trenches to form dielectric isolation bars that isolate portions of the buried power rail layer to form buried power rails and isolate portions of the contacts at the locations between active regions with opposite conductivity.

In some embodiments, the dielectric isolation bars can include a tapered shape having continuous sidewalls through merged contacts formed in the merged contact openings and through the buried power rail layer. The tapered shape can taper from a critical dimension to a sub-lithographic size. The dielectric isolation bars can include a first tapered shape through a single contact and a second tapered shape through the buried power rail layer, where the first tapered shape and the second tapered shape have discontinuous sidewalls relative to each other. The first tapered shape can include a sub-lithographic size. The method can include gouging the active regions and forming the contacts in gouged portions of the active regions.

In one embodiment, a semiconductor device includes a dielectric isolation bar disposed in a region between an n-type active region and a p-type active region. The dielectric isolation bar has a first tapered portion disposed within a contact where the contact connects to one of the n-type active region and the p-type active region and a second tapered portion that cuts through portions of a buried power rail layer, wherein the dielectric isolation bar electrically isolates a lateral portion of the contact from surrounding structures and separates portions of the buried power rail layer. By employing the dielectric isolation bars in accordance with embodiments of the present invention, contacts and power rails have sufficient dielectric material for electrical isolation within the reduced spacings imposed by shrinking device sizes. This is particularly useful where NFETs and PFETs are adjacent to one another in a row of devices as failures in this region are more impactful.

In some embodiments, the first tapered portion and the second tapered portion have discontinuous sidewalls through the contact and the buried power rail layer. The first tapered portion can include a sub-lithographic size. The contact can include a top portion that is narrower that its lower portion. The top portion can be disposed within portions of a dielectric liner. The dielectric isolation bar can overlap the portions of the dielectric liner to provide a continuous dielectric barrier. The contact can extend into a gouged portion of an active region.

In other embodiments, a semiconductor device includes an n-type active region disposed adjacent to a p-type active region and a merged contact having a first portion connecting the n-type active region to a first buried power rail and a second portion connecting the p-type active region to second buried power rail. A dielectric isolation bar is disposed through the merged contact to cut the merged contact into the first portion and the second portion. The dielectric isolation bar is disposed between the first buried power rail and the second buried power rail to electrically isolate the first portion of the merged contact from the second portion of the merged contact and the first buried power rail from the second buried power rail. The dielectric isolation bars in accordance with embodiments of the present invention, electrical isolation is maintained within the reduced spacings imposed by shrinking device sizes. This is particularly useful where NFETs and PFETs are adjacent to one another in a row of devices as failures in this region are more impactful.

In some embodiments, the dielectric isolation bar includes a tapered shape having continuous sidewalls through the merged contact and a buried power rail layer which includes the first buried power rail and the second buried power rail. The tapered shape can taper from a critical dimension to a sub-lithographic size. The first portion of the merged contact and the second portion of the merged contact can each include a top portion that is narrower that its lower portion. The top portion can be disposed within portions of a dielectric liner. The dielectric isolation bar can overlap the portions of the dielectric liner to provide a continuous dielectric barrier. The first portion of the merged contact and the second portion of the merged contact can extend into gouges in the n-type active region and the p-type active region, respectively.

In other embodiments, a semiconductor device includes a first dielectric isolation bar disposed within a single contact between an n-type active region and an adjacent a p-type active region and a second dielectric isolation bar disposed through a merged contact between an n-type active region and an adjacent a p-type active region. The second dielectric isolation bar separates the merged contact to connect one portion of the merged contact to the n-type active region and another portion of the merged contact to the p-type active region. The first dielectric isolation bar and the second dielectric isolation bar pass through a power rail layer to define buried power rails. By employing the dielectric isolation bars in accordance with embodiments of the present invention, contacts and power rails have sufficient dielectric material for electrical isolation within the reduced spacings imposed by shrinking device sizes. This is particularly useful where NFETs and PFETs are adjacent to one another in a row of devices as failures in this region are more impactful.

In some embodiments, the second dielectric isolation bar includes a tapered shape having continuous sidewalls through the merged contact and the power rail layer. The tapered shape can taper from a critical dimension to a sub-lithographic size. The first dielectric isolation bar can include discontinuous sidewalls through the single contact and the power rail layer. The first and second dielectric isolation bars can overlap portions of a dielectric liner to provide a continuous dielectric barrier. At least one contact can include a portion that extends into a gouged portion of an active region.

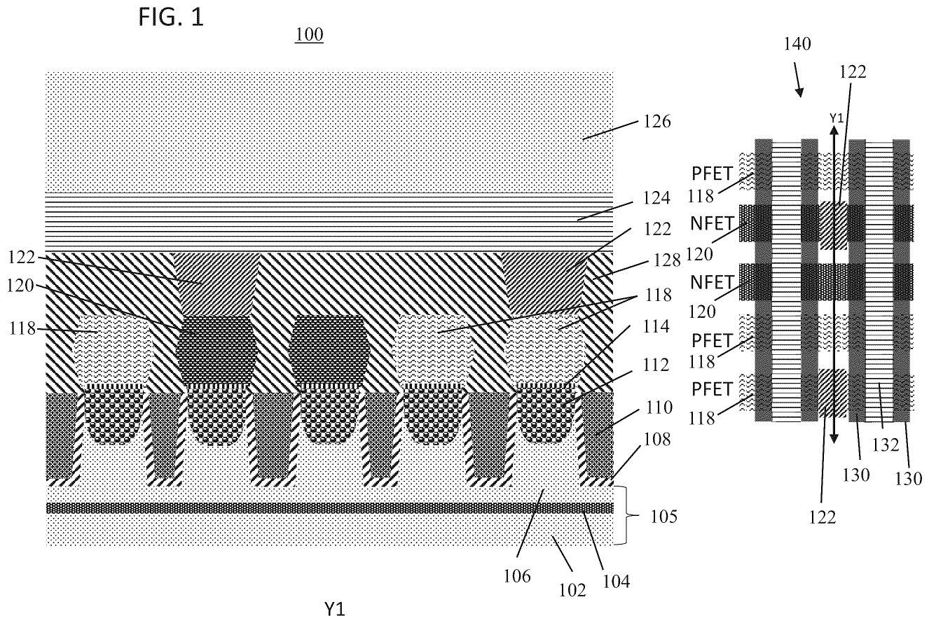

Referring now to the drawings in which like numerals represent the same or similar elements and initially to FIG. 1, devices and methods for manufacturing a stacked field effect transistor (FET) device are shown in accordance with embodiments of the present invention. A wafer 100 includes a substrate 105 having multiple layers on which the stacked FET device will be fabricated. FIG. 1 depicts a cross-sectional view Y1 taken at corresponding section line Y1 of inset 140. Inset 140 shows gates 132 with spacers 130 and active regions 118, 120 for reference. Active regions 118 depict PFETs while active regions 120 depict NFETs. Active regions 118, 120 represent source/drain (S/D) regions for transistor devices, and gates 132 are transverse to the active regions 118, 120. Transistor channels are provided at intersections of gates 132 and the active regions 118, 120 for the transistor devices.

The substrate 105 can include any suitable substrate structure, e.g., a bulk semiconductor, a semiconductor-on-insulator (SOI) substrate, etc., and preferably includes a monocrystalline semiconductor. In one example, the substrate 105 can include a silicon-containing material. Illustrative examples of Si-containing materials suitable for the substrate 105 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 104 formed on the substrate 105 separate substrate portions 102 and 106. The etch stop layer 104 can include an epitaxially grown crystal structure. The etch stop layer 104 includes a material that permits the selective etching and removal of the substrate portion 102 in later steps. In one embodiment, the etch stop layer 104 includes SiGe although depending on the material of the substrate 105, other materials can be selected, e.g., SiGeC, SiC, etc. The substrate portion 102 can include a same material as the substrate portion 106, although other semiconductor materials can be employed, e.g., SiGe, SiGeC, SiC, etc.

A layer stack or stacks (not shown) are applied to or formed on the substrate portion 106. In one embodiment, one or more nanosheets (NS) are applied to the substrate portion 106. In another embodiment, the layer stacks can be epitaxially grown using different chemistries to form layers having different properties. The nanosheet or sheets can be patterned to expose and etch the substrate portion 106.

Substrate portion 106 is etched to form dielectric liner 108 and shallow trenches which are filled to form shallow trench isolation (STI) or STI 110. Dielectric liner 108 and STI 110 can be formed by depositing dielectric material, such as, e.g., SiO₂, SiOₓN_{y}, SiCO or other suitable compounds using, e.g., chemical vapor deposition (CVD), although other deposition methods can be employed. Processing continues with front end of line processing (FEOL), middle end of the line (MOL) and backend of the line (BEOL) fabrication. Sacrificial placeholders 112, active regions 118, 120, gates 132, interlevel dielectric layer 128 and contacts 122 are formed by a number of processes. For example, the gates 132 can be formed using a dummy gate replacement method. The dummy gate material can include a polysilicon, amorphous Si or other selectively removeable material. The regions of the dummy gates have a high dielectric constant (high-K) gate dielectric formed. The dummy gate materials is removed and replaced by a gate metal fill. This process is known as a High-K Metal Gate (HKMG) process to form a gate structure for selectively activating FETs.

A deposition process can be employed to form spacers 130 for the gates 132. Spacers 130 can include an oxide, such as silicon dioxide, although other dielectric materials can be employed.

The sacrificial placeholders 112 can be epitaxially grown in trenches formed in substrate portion 106. The sacrificial placeholder 112 can include SiGe or other epitaxial grown material that can be selectively removed relative to surrounding materials. A buffer layer 114 separates active regions 118, 120 from sacrificial placeholders 112. Buffer layer 114 can include, e.g., Si.

An epitaxial growth process is performed to form active regions 118 and 120. The active regions 118, 120 can be employed for either top or bottom FETs in stacked FET devices. Active regions 118 and 120 are employed to form source and drain (S/D) regions for transistors of the device under construction. Active regions 118 and 120 can include doped Si or SiGe and include faceted surfaces when epitaxial growth is not confined. In one embodiment, the active regions 118 and 120 can be designated as P-type or N-type devices, respectively. The P-type and N-type devices can have different materials selected for the active regions 118 and 120. For example, if the active region 118 is a PFET, boron doped SiGe can be employed. For example, if the active region 120 is an NFET, phosphorous doped Si can be employed. The active regions 118 and 120 can be appropriately doped during the formation of the active regions 118 and 120 during epitaxial growth. It should be understood that other dopants and materials can be employed for the active regions 118 and 120. As shown, P-type and N-type devices can be formed adjacent to one another. Processing could include forming one device type and then the other device type by employing block masks to protect each device during processing of the other.

A dielectric layer 128, such as, e.g., an interlevel dielectric layer (ILD) is formed. The dielectric layer 128 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 128 can be deposited using CVD, although other deposition methods can be employed.

MOL contacts 122 are formed to make connections with the active regions 118 and 120. Trenches or holes are formed in the dielectric layer 128 to expose the active regions 118 and 120. In useful embodiments, a silicide liner, such as Ti, Ni, NiPt is deposited first, then a diffusion barrier can be formed in the trenches prior to a conductive fill. The diffusion barrier can include, e.g., TiN, TaN, or similar materials. A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 122.

Processing continues with the formation of back end of the line (BEOL) layer 124, which can include metal structures and dielectric layers to complete the side for the stacked FET device and provide electrical access to the devices formed. A carrier wafer 126 can be bonded to the BEOL layer 124. The carrier wafer 126 provides support and transportability to the wafer 100 for further processing which includes flipping the wafer 100 for processing the other side of the stacked FET device.

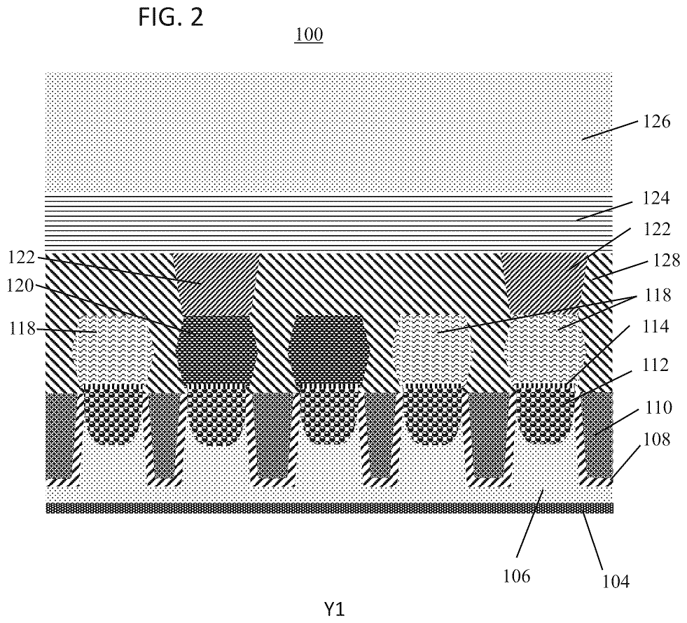

Referring to FIG. 2, to continue processing, the wafer 100 can be flipped to process features on the bottom side of the stacked FET device. However, for clarity and consistency, the stacked FET device will be shown in the FIGS. in a same orientation as previously described with continued and consistent reference to bottom/top. The substrate portion 102 is removed from the bottom side of the stacked FET device. The substrate portion 102 can be removed by an etch process that stops on the etch stop layer 104. In an alternate embodiment, a cleave process can be employed to propagate a crack to remove the substrate portion 102 at the etch stop layer 104.

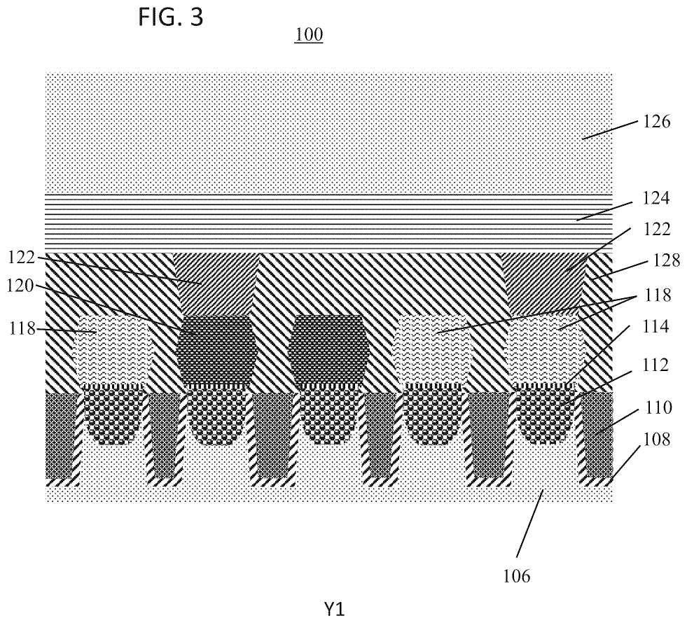

Referring to FIG. 3, the etch stop layer 104 is then removed by an etch process. In an alternate embodiment, a chemical mechanical polish (CMP) process can be employed. With the removal of the etch stop layer 104, the substrate portion 106 is exposed.

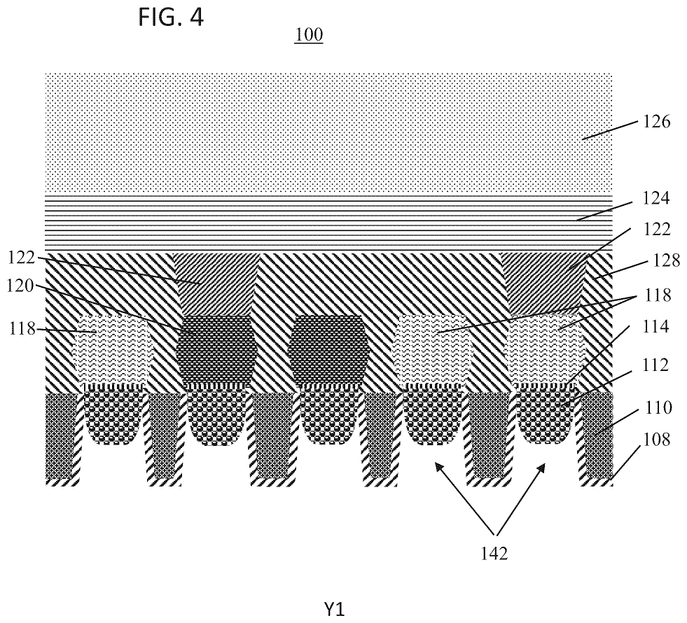

Referring to FIG. 4, the substrate portion 106 is removed by an etch process that selectively removes the material of the substrate portion 106 relative to the dielectric liner 108 and the sacrificial placeholders 112. The removal of the substrate portion 106 leaves openings 142 with the sacrificial placeholders 112 exposed.

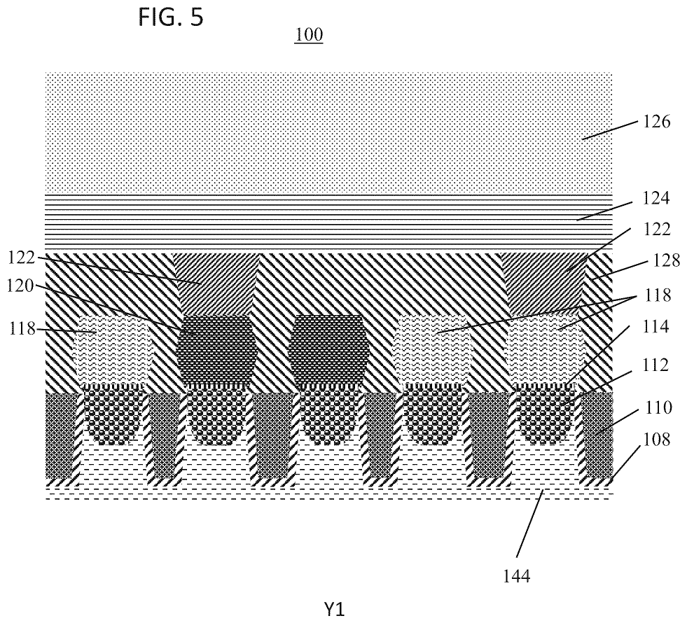

Referring to FIG. 5, a dielectric layer 144 is formed over the dielectric liner 108 and the STI 110, and the sacrificial placeholders 112. The dielectric layer 144 includes a material that is selectively removeable relative to the dielectric liner 108. For example, if the dielectric liner 108 includes a silicon oxide, dielectric layer 144 can include a silicon nitride or silicon oxynitride to be selectively etchable with respect to the dielectric liner 108. The dielectric layer 144 can include the same materials as dielectric layer 128. A CMP process can be employed to planarize the free surface of the dielectric layer 144.

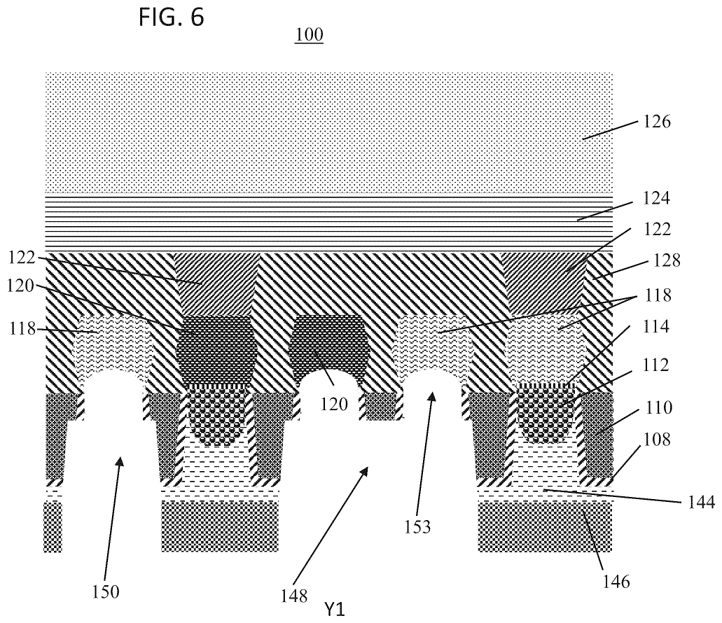

Referring to FIG. 6, backside contacts are formed to make connections with the active regions 118 and 120. A patternable material is deposited or spun onto a surface of the wafer 100 over dielectric layer 144. In one embodiment, an organic planarization layer (OPL) 146 is formed over the wafer 100. In some embodiments, an anti-reflective coating (ARC) layer (not shown) may be formed on the OPL 146 followed by a layer of photoresist formed on the ARC layer. The layer of photoresist can be imaged with an image pattern and developed to form an etch mask. Due to the size of the active regions 118, 120, openings 148, 150 need to be sized to permit lithographic patterning. In one embodiment, merged contact openings 148 can be employed. Due to merging adjacent contact holes a lithographic resolution threshold is exceeded to permit the use of lithographic patterning techniques. Backside contact patterning in a closed NFET/PFET space can employ merged contact patterning. However, the merged contacts need to be electrically isolated as will be described.

The OPL 146 can be etched in accordance with the etch mask to open up trenches or openings 148, 150 in the OPL 146 that expose sacrificial placeholders 112. Etching can continue to remove the sacrificial placeholders 112 in openings 148, 150 as well as portions of dielectric liner 108 and STI 110. Next, gouges 153 can optionally be formed in bottoms of the exposed active regions in openings 148 and 150 by continuing to etch. The openings 148, 150 are accurately controlled by an anisotropic etch, e.g., a reactive ion etch (RIE) etch or ion beam etch (IBE etch). The anisotropic etch, such as a plasma dry etch, is accurately controlled since a lithographic process is employed. A frontside lithographic process, e.g., can have overlay error of three standard deviations <5 nm.

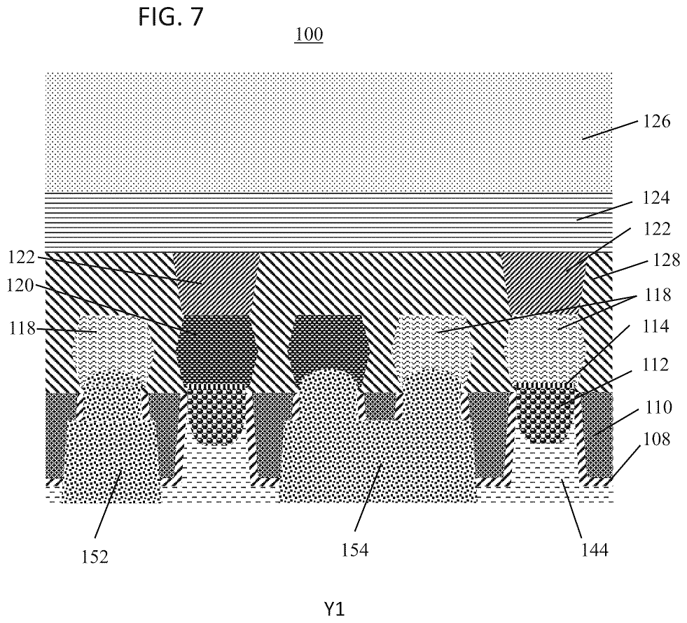

Referring to FIG. 7, the OPL 146 is stripped or removed from the wafer 100. The OPL can be removed by employing an ashing process. A pre-silicide clean process can be performed to clean surfaces in preparation for siliciding exposed surfaces of the active regions 118, 120.

In useful embodiments, a silicide liner, such as Ti, Ni, NiPt is deposited first, then a diffusion barrier can be formed in the openings 148, 150 prior to a conductive fill. The diffusion barrier can include, e.g., TiN, TaN, or similar materials. A conductive fill is performed to fill the openings 148, 150. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form a contact 152 (a single contact) and a merged contact 154. Contact 152 connects to an active region 118 for a PFET. Merged contact 154 connects to active regions 120, 118 for an adjacent NFET and PFET, respectively.

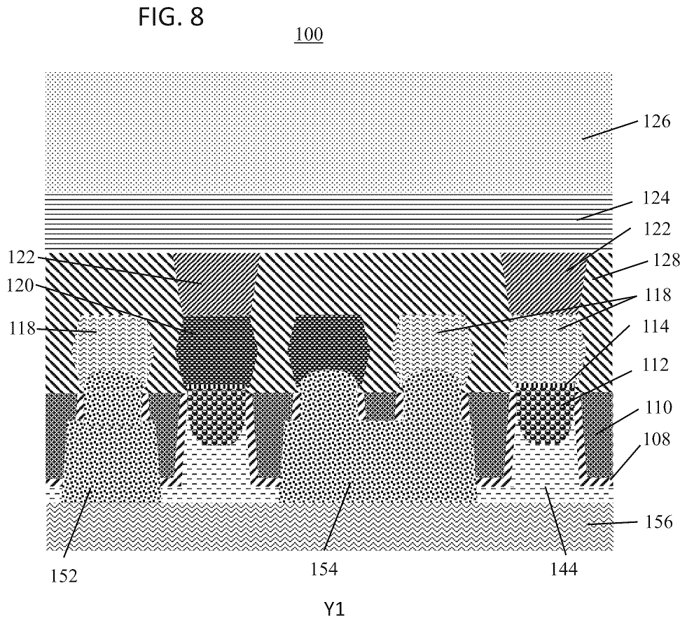

Referring to FIG. 8, a backside interconnect layer 156, which will be employed to form metal structures and dielectric layers to complete the bottom side of the stacked FET device and provide electrical access to the devices is formed. The backside interconnect layer 156 can be employed to form backside power rails (BPR) for a backside power distribution network. The backside interconnect layer 156 is formed on the dielectric layer 144 and the backside contacts 152, 154.

The backside interconnect layer 156 can include a deposition of one or more metal layers. In one embodiment, the metal layer can include Ru, although other metals can be employed, e.g., Cu, W, Mo, Rh, Ir, etc. The backside interconnect layer 156 can be deposited by a CVD deposition process, although other deposition processes can be employed.

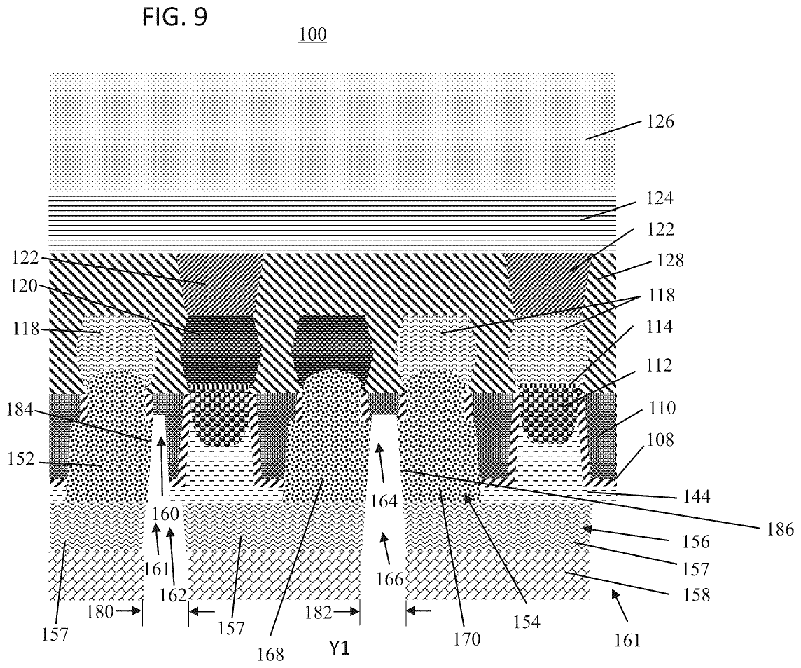

Referring to FIG. 9, a subtractive metal etch process is employed to pattern the backside interconnect layer 156 in a backside S/D contact metal etch process. In one embodiment, a hard mask 158 may be formed by blanket depositing a layer of hard mask material, providing a patterned photoresist on top of the layer of hard mask material, and then etching the layer of hard mask material to provide the hard mask pattern for etching the backside interconnect layer 156. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask 158 by an etch process.

The hard mask 158 is patterned using a lithographic patterning process. Trenches or holes 162, 166 are formed through the backside interconnect layer 156 to form metal lines 157. Trenches or holes 162, 166 can be formed by employing an anisotropic etch., e.g., RIE and patterned in accordance with the hard mask 158. By using lithographic patterning techniques to pattern the hard mask 158, widths 180, 182 can provide a smallest possible critical dimension for trenches or holes 162, 166. A same or different anisotropic etch., e.g., RIE, can continue to etch trenches or holes 162, 166 beyond the backside interconnect layer 156.

In one embodiment, etching continues to form trench 160. Trench 160 is disposed between an active region 118 for a PFET and an active region 120 for an NFET. Opening 161 is formed through the backside interconnect layer 156 and includes a critical dimension 180 that can be a smallest achievable dimension with lithographic patterning. Since the etching process is selective to metal materials, opening 161 extends into contact 152 to form a trench 160. Trench 160 includes a sub-lithographic width that extends into contact 152 and can include a tapered shape 184. The tapered shape 184 and opening 161 can have an abrupt transition therebetween since the etching removes less dielectric material than metal. Some dielectric material is removed, e.g., portions of dielectric liner 108 and STI 110 to form the tapered shape 184 of trench 160.

In one embodiment, etching continues to form trench 164. This etching can be contemporaneous and employ the same etching process as used to form trench 160. In another embodiment, a separate etching process can be employed to form trenches 160 and 164. Trench 164 is disposed between an active region 118 for a PFET and an active region 120 for an NFET. Opening 166 is formed through the backside interconnect layer 156 and includes a critical dimension 182 that can be a smallest achievable dimension with lithographic patterning. Since the etching process is selective to metal materials, opening 166 extends into merged contact 154 to form trench 164. Trench 164 includes a sub-lithographic width that extends into merged contact 154 and can include a tapered shape 186. The tapered shape 186 splits the merged contact 154 into two portions contact 168 and contact 170. The tapered shape 186 extends into the dielectric liner 108 and STI 110.

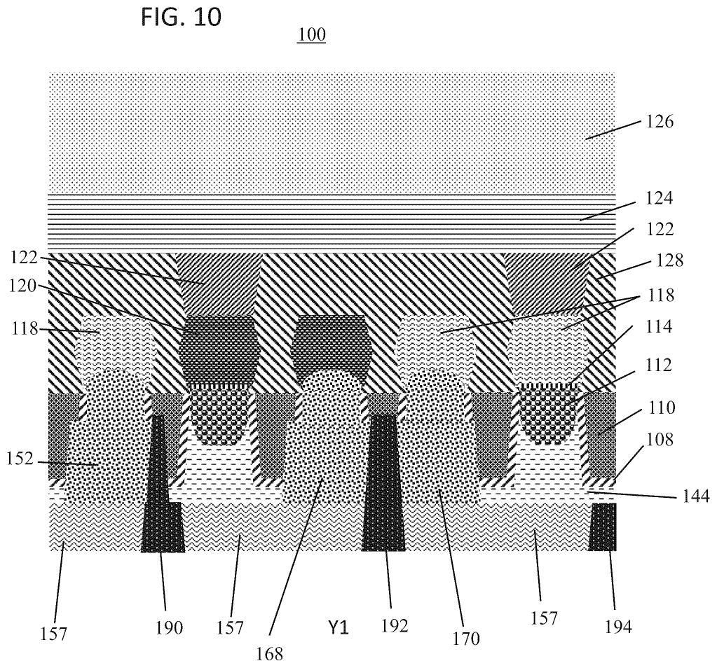

Referring to FIG. 10, the hard mask 158 is stripped or removed by employing an etch process or planarization process. A dielectric fill is performed to fill in trenches 162, 166 including portions 160, 161 and 164 for backside contact and buried power rail (BPR) isolation. The dielectric fill can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric fill can be deposited using CVD, although other deposition methods can be employed. A planarization process, e.g., CMP can be employed to remove access material from a backside surface of the wafer 100.

A dielectric isolation bar 190 is formed and provides isolation alongside contact 152 between active regions 118 and 120 having opposite conductivity. The dielectric isolation bar 190 also electrically isolates metal lines 157. A dielectric isolation bar 192 is formed and provides isolation through a merged contact 154 to provide contacts 168 and 170. The dielectric isolation bar 192 is disposed between active regions 118 and 120 having opposite conductivity. The dielectric isolation bar 192 also electrically isolates metal lines 157. A portion of another dielectric isolation bar 194 is also shown which defines metal lines 157.

In embodiments of the present invention, dielectric isolation bars 190, 192 are employed to isolate backside power rails (e.g., metal lines 157). The dielectric isolation bars 190, 192 can include sub-lithographic sized components that provide isolation between contacts and metal lines at different levels of the device. Dielectric isolation bar 192 is employed to isolate merged backside S/D contacts 168, 170 between an NFET and a PFET. The dielectric isolation bar 190 also can be employed to provide dielectric isolation between an NFET and a PFET. The dielectric isolation bars 190, 192 have a lower portion that isolates the backside power rails (metal lines 157) and an upper portion cuts into or through the backside S/D contacts 152, 168, 170. The backside S/D contacts 152, 168, 170 connect to the metal lines 157 of the buried power rails (BPR), The BPR provide supply voltages (VDD, VSS) and signal lines for operations of the semiconductor device.

In one embodiment, the dielectric isolation bar 192 can cut through a merged backside S/D contact in a region between an NFET and a PFET and have continuous sidewalls throughout a lower portion and an upper portion. In another embodiment, the dielectric isolation bar 190 cuts through a single backside S/D contact under either the NFET or the PFET and has a discontinuous dimension, where a lower portion dimension is larger than an upper portion dimension. For example, one dielectric isolation bar includes an upper portion and a lower portion that have sidewalls that are continuous. Another dielectric isolation bar includes sidewalls that are discontinuous from an upper portion to a lower portion and the lower portion follows the sidewall angle of a backside S/D contact.

In accordance with the present embodiments, dielectric isolation bars are employed which can begin with lithographic critical dimensions but are reduced by employing etch chemistries that provide a tapered sidewall for an etched hole or trench for the dielectric isolation bars. This enables the use of smaller epi regions, merged contacts between transistors that need to be electrically isolated, and a scaling up level for connections to power distribution wiring. Dielectric isolation is therefore provided at locations where it is most needed and without occupying additional space or width.

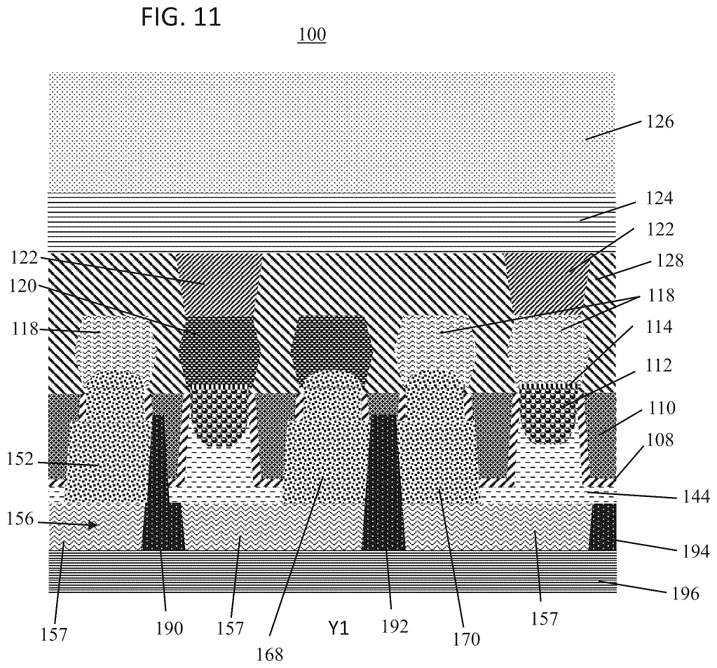

Referring to FIG. 11, a backside power distribution network (BSPDN) 196 is formed over the metal lines 157 of the backside interconnect layer 156. A stacked FET device 200 is provided having FETs formed in at least two layers. A semiconductor device such as stacked FET device 200 includes a stacked transistor structure having field effect transistors on at least two levels. The at least two levels include a top side and bottom side. Active regions 118 and 120 with opposite conductivity types can employ dielectric isolation bars to enable the use of merged contacts, provide additional isolation for contact especially between active regions of opposite conductivity and separate buried power rails.

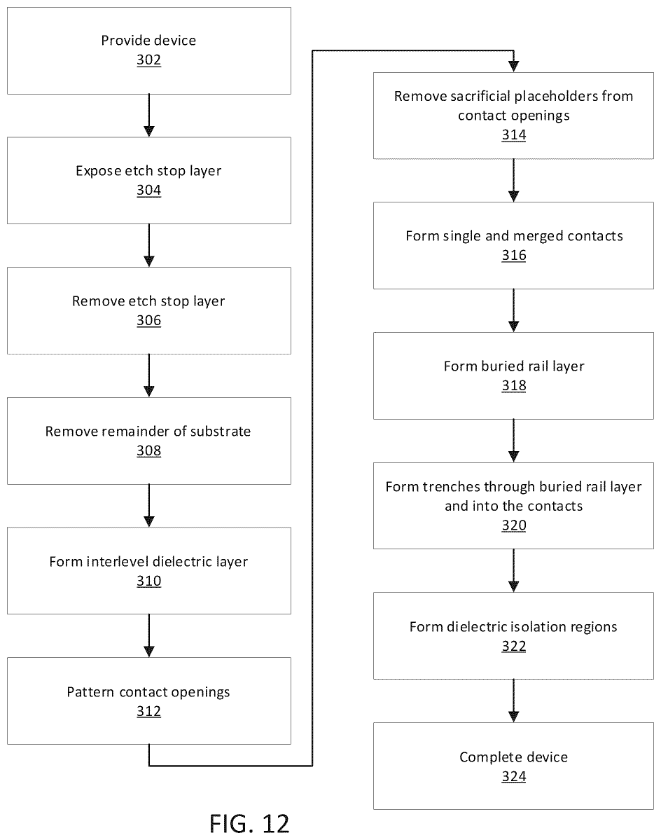

Referring to FIG. 12, methods for fabrication of a semiconductor device are described in accordance with embodiments of the present invention. In block 302, a partially fabricated semiconductor device is provided that includes active regions formed over sacrificial placeholders which are associated with the active regions. The device can include a top layer with FETs already fabricated. The present embodiments can be applied to a single layer device or a stacked FET device. The dielectric isolation bars can be employed on a top layer, a bottom layer or both. A dielectric liner lines shallow trench isolation regions which are filled with dielectric material. The shallow trench isolation regions are formed in a substrate, which is provided having an etch stop layer separating portions of the substrate. In block 304, the etch stop layer is exposed. In block 306, the etch stop layer is removed. In block 308, the remaining portion of the substrate is removed to expose a dielectric liner covering the shallow trench isolation regions and to expose the sacrificial placeholders associated with active regions. In block 310, an interlevel dielectric layer is formed over the dielectric liner and the sacrificial placeholders.

In block 312, contact openings are patterned in the interlevel dielectric layer. The contact openings can include single contact openings and merged contact openings.

In block 314, the sacrificial placeholders are removed from the contact openings. In block 315, the active regions can be further etched to form gouges therein. The gouges can increase contact surface area and reduce contact resistance. In block 316, contacts are formed in the single contact openings and the merged contact openings at locations between active regions with opposite conductivity. In block 317, the contacts can be formed in the gouged portions of the active regions. The contacts can include a top portion that is narrower that its lower portion. The top portion can be formed within or bordered by portions of a dielectric liner. This top portion can include a gouged portion of the contact that interfaces with the active region.

In block 318, a buried rail layer is deposited in contact with the contacts. In block 320, trenches are formed through the buried rail layer and into the contacts. In block 322, a dielectric fill is deposited in the trenches to form dielectric isolation regions that isolate portions of the buried rail layer to form buried power rails and isolate portions of the contacts at the locations between active regions with opposite conductivity. In this way, a continuous dielectric barrier is formed from the dielectric liner through the buried rail layer by the dielectric isolation bars.

The dielectric isolation bar can include a tapered shape having continuous sidewalls through merged contacts formed in the merged contact openings and through the buried power rail layer. The tapered shape can taper from a critical dimension to a sub-lithographic size. The dielectric isolation bar into the single contacts can include a first tapered shape through the single contact and a second tapered shape through the buried power rail layer, wherein the first tapered shape and the second tapered shape have discontinuous sidewalls relative to each other. The first tapered shape can include a sub-lithographic size.

In block 324, processing continues with the formation of backside power distribution network (BSPDN), removal of carrier wafer and the completion of the device.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a dielectric isolation bar disposed in a region between an n-type active region and a p-type active region, the dielectric isolation bar having:
a first tapered portion disposed within a contact where the contact connects to one of the n-type active region and the p-type active region; and
a second tapered portion that cuts through portions of a buried power rail layer, wherein the dielectric isolation bar electrically isolates a lateral portion of the contact from surrounding structures and separates portions of the buried power rail layer.

2. The semiconductor device as recited in claim 1, wherein the first tapered portion and the second tapered portion have discontinuous sidewalls through the contact and the buried power rail layer.

3. The semiconductor device as recited in claim 1, wherein the first tapered portion includes a sub-lithographic size.

4. The semiconductor device as recited in claim 1, wherein the contact includes a top portion that is narrower that its lower portion.

5. The semiconductor device as recited in claim 4, wherein the top portion is disposed within portions of a dielectric liner.

6. The semiconductor device as recited in claim 5, wherein the dielectric isolation bar overlaps the portions of the dielectric liner to provide a continuous dielectric barrier.

7. The semiconductor device as recited in claim 1, wherein the contact extends into a gouged portion of an active region.

8. A semiconductor device, comprising:
an n-type active region disposed adjacent to a p-type active region;
a merged contact having a first portion connecting the n-type active region to a first buried power rail and a second portion connecting the p-type active region to second buried power rail; and
a dielectric isolation bar disposed through the merged contact to cut the merged contact into the first portion and the second portion, the dielectric isolation bar disposed between the first buried power rail and the second buried power rail to electrically isolate the first portion of the merged contact from the second portion of the merged contact and the first buried power rail from the second buried power rail.

9. The semiconductor device as recited in claim 8, wherein the dielectric isolation bar includes a tapered shape having continuous sidewalls through the merged contact and a buried power rail layer which includes the first buried power rail and the second buried power rail.

10. The semiconductor device as recited in claim 9, wherein the tapered shape tapers from a critical dimension to a sub-lithographic size.

11. The semiconductor device as recited in claim 8, wherein the first portion of the merged contact and the second portion of the merged contact each include a top portion that is narrower that its lower portion.

12. The semiconductor device as recited in claim 11, wherein the top portion is disposed within portions of a dielectric liner.

13. The semiconductor device as recited in claim 12, wherein the dielectric isolation bar overlaps the portions of the dielectric liner to provide a continuous dielectric barrier.

14. The semiconductor device as recited in claim 8, wherein the first portion of the merged contact and the second portion of the merged contact each include a portion that extends into gouges in the n-type active region and the p-type active region, respectively.

15. A semiconductor device, comprising:
a first dielectric isolation bar disposed within a single contact between an n-type active region and an adjacent a p-type active region; and
a second dielectric isolation bar disposed through a merged contact between an n-type active region and an adjacent a p-type active region, the second dielectric isolation bar separating the merged contact to connect one portion of the merged contact to the n-type active region and another portion of the merged contact to the p-type active region;
the first dielectric isolation bar and the second dielectric isolation bar pass through a power rail layer to define buried power rails.

16. The semiconductor device as recited in claim 15, wherein the second dielectric isolation bar includes a tapered shape having continuous sidewalls through the merged contact and the power rail layer.

17. The semiconductor device as recited in claim 16, wherein the tapered shape tapers from a critical dimension to a sub-lithographic size.

18. The semiconductor device as recited in claim 15, wherein the first dielectric isolation bar includes discontinuous sidewalls through the single contact and the power rail layer.

19. The semiconductor device as recited in claim 15, wherein the first and second dielectric isolation bars overlap portions of a dielectric liner to provide a continuous dielectric barrier.

20. The semiconductor device as recited in claim 15, wherein at least one contact includes a portion that extends into a gouged portion of an active region.
